(19) United States
(12) Patent Application Publication
(10) Pub. No.: US 2012/0062081 A1
(43) Pub. Date: Mar. 15, 2012

(54) HOUSING AND METHOD FOR MANUFACTURING HOUSING

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); MAN-XI ZHANG, Shenzhen (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/981,720

(22) Filed: Dec. 30, 2010

(30) Foreign Application Priority Data
Sep. 10, 2010 (CN) 201010278414.2

(51) Int. Cl. H05K 5/00; C23C 14/02; C23C 14/14; C23C 14/35

(52) U.S. Cl. 312/223.1; 204/192.15

(57) ABSTRACT

A housing includes a substrate; an aluminum layer deposited on the substrate; and an ion implantation layer formed on the aluminum layer, the ion implantation layer comprising aluminum(II) oxide solid solution phase and aluminum oxide solid solution phase. The disclosure further includes a method for manufacturing the housing. The method includes the following steps: providing a substrate made of aluminum alloy; depositing an aluminum layer on the substrate, the aluminum layer is deposited on the substrate with an aluminum target by magnetron sputtering process; and forming an ion implantation layer on the aluminum layer, the ion implantation layer is formed on the aluminum layer by implanting ions of oxygen into the aluminum layer, and the ion implantation layer comprising aluminum(II) oxide solid solution phase and aluminum oxide solid solution phase.

### BACKGROUND

1. Technical Field

The disclosure generally relates to housings for electronic devices and method for manufacturing the housings.

2. Description of Related Art

With the development of wireless communication and information processing technology, portable electronic devices such as mobile telephones and electronic notebooks are now in widespread use. Aluminum alloy has good heat dissipation and can effectively shield electromagnetic interference so aluminum alloy are widely used to manufacture housings of the portable electronic devices. However, aluminum alloy has a low corrosion resistance.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary housing and method for manufacturing the housing. Moreover, in the drawings like reference numerals designate corresponding parts throughout the several views. Wherever possible, the same reference numbers are used throughout the drawings to refer to the same or like elements of an embodiment.

FIG. 1 illustrates a cross-sectional view of an embodiment of a housing.

FIG. 2 is a diagram for manufacturing the housing in FIG. 1.

FIG. 3 is a schematic view of a magnetron sputtering coating machine for manufacturing the housing in FIG. 1.

### DETAILED DESCRIPTION

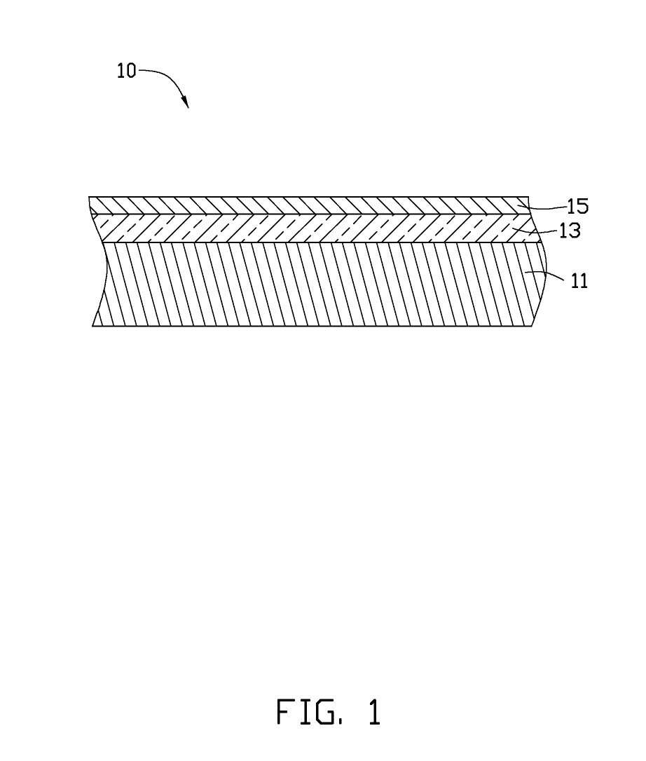

Referring to FIG. 1, a housing 10 includes a substrate 11, an aluminum layer 13 deposited on the substrate 11, and an ion implantation layer 15. The housing 10 may be for an electronic device. The substrate 11 may be made of aluminum alloy. The aluminum layer 13 is made of aluminum. The aluminum layer 13 has a thickness ranging from about 0.5 micrometer to about 1.0 micrometer. The aluminum layer 13 may be deposited by magnetron sputtering process or cathodic arc deposition. The ion implantation layer 15 comprises aluminum(II) oxide (AlO) solid solution phase and aluminum oxide (Al2O3) solid solution phase.

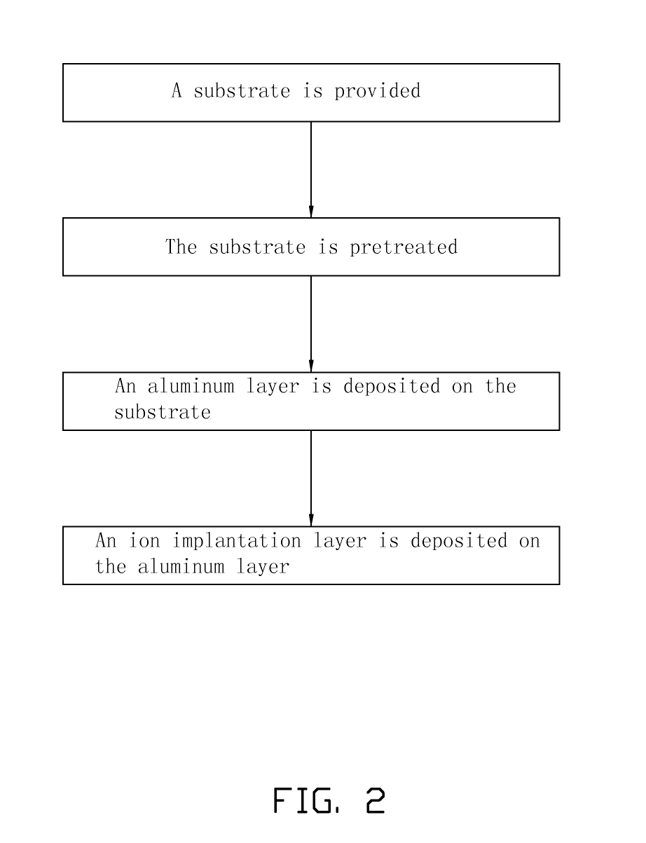

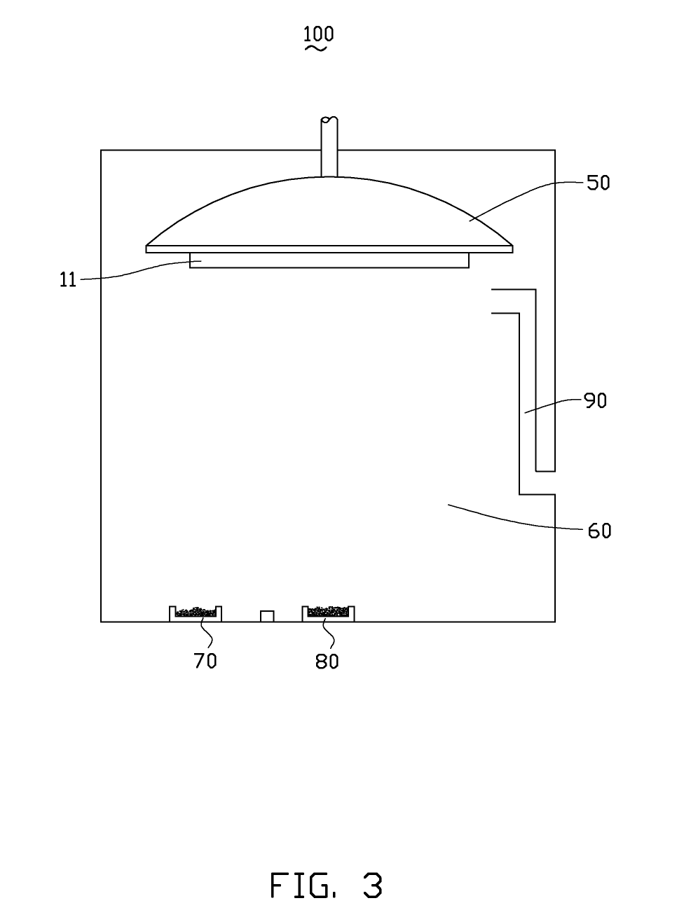

Referring to FIGS. 2 and 3, a method for manufacturing the housing 10 may includes at least the following steps.

A substrate 11 is provided. The substrate 11 may be made of aluminum alloy and may be molded by a punching method.

The substrate 11 is pretreated. First, the substrate 11 is treated to remove oxide film on surface thereof by mechanical lapping, until the substrate 11 has a surface roughness Rz is less than 1.2 micrometer. Second, the substrate 11 is washed with a solution (e.g., alcohol or acetone) in an ultrasonic cleaner to remove grease, dirt, and/or impurities. The substrate 11 is then dried.

An aluminum layer 13 is deposited on the substrate 11. In an exemplary embodiment, the substrate 11 is retained on a rotating bracket 50 in a vacuum chamber 60 of a vacuum coating machine 100. The temperature in the vacuum chamber 60 is adjusted to about 50° C. to about 180° C. The vacuum level of the vacuum chamber 60 is adjusted to about 8.0×10⁻³ Pa. Pure argon (99.999%) is pumped into the vacuum chamber 60 at a flux of about 100 standard cubic centimeters per minute (sccm) to about 300 sccm from a gas inlet 90. A bias voltage is applied to the substrate 11 in a range from about −50 volts to about −300 volts. An aluminum target 70 is evaporated at a power from about 5 kw to about 10 kw for about 30 minutes to about 90 minutes, to deposit the aluminum layer 13 on the substrate 11. In another embodiment, the substrate 11 may be processed by cathodic arc deposition, ion implantation or plasma cleaning.

The electrode potential of aluminum is equivalent to the electrode potential of aluminum alloy, so it is difficult to cause galvanic corrosion between the substrate 11 and the aluminum layer 13. Thus, the aluminum layer 13 can improve the corrosion resistance of the substrate 11. Galvanic corrosion is an electrochemical process in which one metal corrodes preferentially to another when both metals are in electrical contact and immersed in an electrolyte.

An ion implantation layer 15 is formed on the aluminum layer 13 by ion implantation process. The vacuum level of the vacuum chamber 60 is adjusted to about 3.0×10⁻³ Pa. Pure oxygen (99.999%) is pumped to an ion source 80 in the vacuum coating machine 100 from the gas inlet 90. The ion source 80 is started at a power from about 0.5 kw to about 5 kw for about 30 minutes to about 120 minutes, to produce ions of oxygen. The ions of oxygen produced by the ion source 80, are then electrotatically accelerated to a high energy, and the aluminum layer 13, i.e., the ions of oxygen are implanted into the aluminum layer 13. During this processing, the physical properties of the aluminum layer 13 is changed, to produce the ion implantation layer 15 mainly comprising aluminum(II) oxide (AlO) solid solution phase and aluminum oxide (Al2O3) solid solution phase. The aluminum(II) oxide (AlO) solid solution phase and Al2O3 solid solution phase can prevent columnar crystal from forming in the ion implantation layer 15, thereby improving the compactness of the ion implantation layer 15. Thus, the corrosion resistance of the housing 10 can be improved.

Depending on the embodiment, certain of the steps described below may be removed, others may be added, and the sequence of steps may be altered. It is also to be understood that the description and the claims drawn to a method may include some indication in reference to certain steps. However, the indication used is only to be viewed for identification purposes and not as a suggestion as to an order for the steps.

It is to be understood, however, that even through numerous characteristics and advantages of the disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A housing, comprising:
a substrate;
an aluminum layer deposited on the substrate; and
an ion implantation layer formed on the aluminum layer, the ion implantation layer comprising aluminum(II) oxide solid solution phase and aluminum oxide solid solution phase.

2. The housing as claimed in claim 1, wherein the substrate is made of aluminum alloy.

3. The housing as claimed in claim 1, wherein the aluminum layer is made of aluminum.

4. The housing as claimed in claim 1, wherein the aluminum layer has a thickness ranging from about 0.5 micrometer to about 1.0 micrometer.

5. The housing as claimed in claim 1, wherein the aluminum layer is deposited by magnetron sputtering process or cathodic arc deposition.

6. The housing as claimed in claim 1, wherein the ion implantation layer is deposited on the aluminum layer by ion implantation process.

7. A method for manufacturing a housing, the method comprising:
providing a substrate made of aluminum alloy;
depositing an aluminum layer on the substrate, wherein the aluminum layer is deposited on the substrate with an aluminum target by magnetron sputtering process; and
forming an ion implantation layer on the aluminum layer, wherein the ion implantation layer is formed on the aluminum layer by implanting ions of oxygen into the aluminum layer, and the ion implantation layer comprising aluminum(II) oxide solid solution phase and aluminum oxide solid solution phase.

8. The method of claim 7, wherein during depositing the aluminum layer on the substrate, first providing a vacuum coating machine having a vacuum chamber, the aluminum target and a rotating bracket, the aluminum target and the rotating bracket are both located in the vacuum chamber; the substrate is retained on the rotating bracket; the temperature in the vacuum chamber is adjusted to about 50° C. to about 180° C.; a vacuum level of the vacuum chamber is adjusted to about 8.0×10⁻³ Pa; pure argon is pumped into the vacuum chamber at a flux of about 100 sccm to about 300 sccm; a bias voltage is applied to the substrate in a range from about −50 volts to about −300 volts; the aluminum target is evaporated at a power from about 5 kw to about 10 kw for about 30 minutes to about 90 minutes, to deposit the aluminum layer on the substrate.

9. The method of claim 8, wherein during forming the ion implantation layer on the aluminum layer, the vacuum level of the vacuum chamber is adjusted to about 3.0×10⁻³ Pa;
pure oxygen is pumped to an ion source in the vacuum coating machine, the ion source is started at a power from about 0.5 kw to about 5 kw for about 30 minutes to about 120 minutes, to produce oxygen ions which are implanted into the aluminum layer to produce the ion implantation layer.

10. The method of claim 8, further comprising a step of pretreating the substrate before depositing the aluminum layer on the substrate; pretreating the substrate comprising the substrate is treated to remove oxide film on surface thereof by mechanical lapping, until the substrate has a surface roughness Rz is less than 1.2 micrometer.

11. The method of claim 10, wherein pretreating the substrate further comprises the substrate is washed with a solution in an ultrasonic cleaner to remove grease, dirt, and/or impurities.

12. The method of claim 11, wherein pretreating the substrate further comprises drying the substrate after washing the substrate.
